(19) United States
(12) Patent Application Publication
(10) Pub. No.: US 2010/0081273 A1
(43) Pub. Date: Apr. 1, 2010

(54) METHOD FOR FABRICATING CONDUCTIVE PATTERN

(75) Inventors: Jung-Yuan Hsieh, Hsinchu City (TW); Yung-Ching Chen, Nantou County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 12/242,850

(22) Filed: Sep. 30, 2008

(51) Int. Cl. H01L 21/768

(52) U.S. Cl. 438/652; 257/E21.576

(57) ABSTRACT

A method for fabricating a conductive pattern including following steps is provided. A first conductive layer is formed on a substrate. A patterned hard mask layer is formed on the first conductive layer. A portion of the first conductive layer is removed to expose a portion of the substrate by using the patterned hard mask layer as a mask. A dielectric layer covering the patterned hard mask layer is formed on the substrate. A portion of the dielectric layer is removed to expose the patterned hard mask layer. The patterned hard mask layer is removed to form an opening in the dielectric layer. A second conductive layer is formed in the opening.

### BACKGROUND OF THE INVENTION

1. Field of the Invention

The present invention relates to a semiconductor manufacturing process. More particularly, the present invention relates to a method for fabricating a conductive pattern.

2. Description of Related Art

With advancement of technologies, the level of integration of electronic devices is required to be increased, so as to comply with current demands for lightness, thinness, shortness, smallness, and compactness. In order to improve the level of integration, not only dimensions of semiconductor devices can be reduced, but also the distance between semiconductor components can be decreased. Nevertheless, either the size reduction of the semiconductor devices or the decrease in the distance between the semiconductor components may result in certain issues.

For example, as the dimension of a semiconductor device continues to decrease, the dimensions of conductive wires in the semiconductor device are correspondingly reduced. Accordingly, an aspect ratio of the conductive wires becomes greater and greater, giving rise to difficulties in manufacturing the conductive wires.

A method for manufacturing the conductive wires is proposed according to the related art. Specifically, a reactive ion etching process is performed on a conductive layer with use of a patterned mask layer, so as to form the conductive wires having a predetermined height. However, due to the excessive aspect ratio of the conductive wires, the conductive wires are prone to be distorted or collapsed. Moreover, voids may be formed in a dielectric layer interposed between the two adjacent conductive wires in subsequent processes. Either the distortion and collapse of the conductive wires or the voids in the dielectric layer deteriorate the performance of the semiconductor device.

On the other hand, a damascene method is also proposed for manufacturing the conductive wires according to the related art. Nevertheless, a coupling effect may occur between the two adjacent conductive wires fabricated by conducting the damascene method, thus resulting in a drop in the performance of the semiconductor device. Additionally, a barrier layer is formed in an opening during the fabrication of the conductive wires by means of the damascene method, such that it is much more unlikely for the opening to be filled with conductive materials.

### SUMMARY OF THE INVENTION

In view of the foregoing, the present invention is directed to a method for effectively fabricating a conductive pattern characterized by satisfactory quality.

The present invention provides a method for fabricating a conductive pattern. The method includes following steps. A first conductive layer is formed on a substrate. A patterned hard mask layer is formed on the first conductive layer. A portion of the first conductive layer is removed by using the patterned hard mask layer as a mask, so as to expose a portion of the substrate. A dielectric layer covering the patterned hard mask layer is formed on the substrate. A portion of the dielectric layer is removed to expose the patterned hard mask layer. The patterned hard mask layer is removed to form an opening in the dielectric layer. A second conductive layer is formed in the opening.

According to an embodiment of the present invention, in the method for fabricating the conductive pattern, the conductive pattern is, for example, a conductive wire.

According to an embodiment of the present invention, in the method for fabricating the conductive pattern, the first conductive layer is, for example, made of metal.

According to an embodiment of the present invention, in the method for fabricating the conductive pattern, the first conductive layer is, for example, formed by performing a physical vapor deposition process.

According to an embodiment of the present invention, in the method for fabricating the conductive pattern, the patterned hard mask layer is, for example, made of carbon.

According to an embodiment of the present invention, in the method for fabricating the conductive pattern, the patterned hard mask layer is, for example, made of a photoresist material.

According to an embodiment of the present invention, in the method for fabricating the conductive pattern, the patterned hard mask layer is, for example, formed by performing following steps. A hard mask material layer is formed on the first conductive layer. The hard mask material layer is patterned.

According to an embodiment of the present invention, in the method for fabricating the conductive pattern, the portion of the first conductive layer is, for example, removed by performing a dry etching process.

According to an embodiment of the present invention, in the method for fabricating the conductive pattern, the dielectric layer is, for example, made of silicon oxide.

According to an embodiment of the present invention, in the method for fabricating the conductive pattern, the dielectric layer is, for example, formed by performing a chemical vapor deposition process.

According to an embodiment of the present invention, in the method for fabricating the conductive pattern, the portion of dielectric layer is, for example, removed by performing an etching back process.

According to an embodiment of the present invention, in the method for fabricating the conductive pattern, the portion of dielectric layer is, for example, removed by performing a chemical-mechanical polishing process.

According to an embodiment of the present invention, in the method for fabricating the conductive pattern, the patterned hard mask layer is, for example, removed by performing a dry etching process.

According to an embodiment of the present invention, in the method for fabricating the conductive pattern, the patterned hard mask layer is, for example, removed by performing a wet etching process.

According to an embodiment of the present invention, in the method for fabricating the conductive pattern, the second conductive layer is, for example, made of metal.

According to an embodiment of the present invention, in the method for fabricating the conductive pattern, the second conductive layer is, for example, formed by performing following steps. A conductive material layer is formed on the dielectric layer. Here, the opening is filled with the conductive material layer. The conductive material layer outside the opening is removed.

According to an embodiment of the present invention, in the method for fabricating the conductive pattern, the conductive material layer is, for example, formed by performing a physical vapor deposition process.

According to an embodiment of the present invention, in the method for fabricating the conductive pattern, the conductive material layer outside the opening is, for example, removed by performing a chemical-mechanical polishing process.

In light of the foregoing, the conductive pattern is formed step by step in the method for fabricating the conductive pattern according to the present invention. As such, the distortion or collapse of the conductive pattern can be prevented, and the conductive pattern with outstanding quality can be manufactured. In addition, by performing the method for fabricating the conductive pattern according to the present invention, the formation of the voids in the dielectric layer between the conductive patterns can be avoided, so as to improve the performance of the semiconductor device.

In order to make the above and other objects, features and advantages of the present invention more comprehensible, an embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A through 1E are schematic cross-sectional flowcharts showing a process for fabricating a conductive pattern according to an embodiment of the present invention.

### DESCRIPTION OF EMBODIMENTS

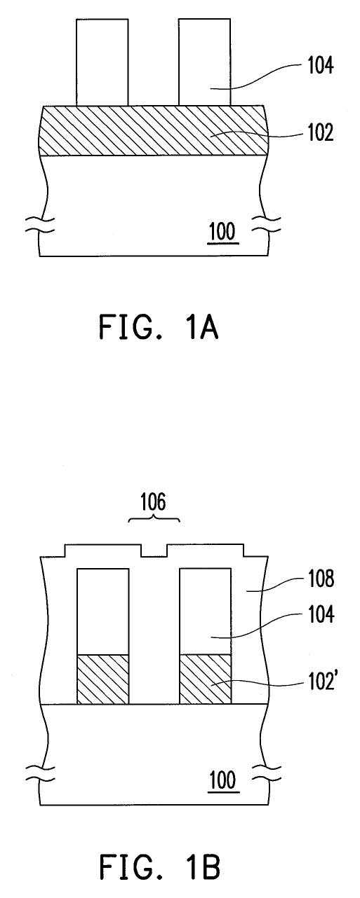

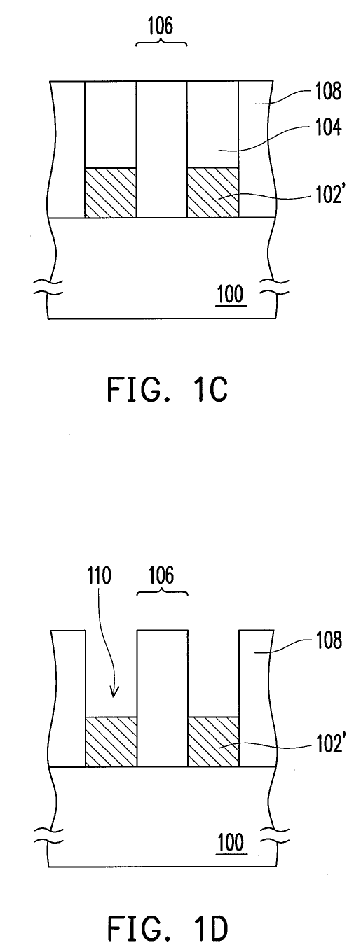

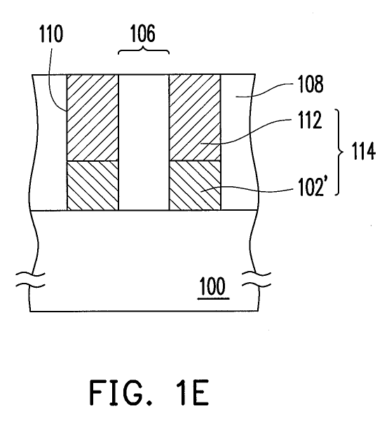

FIGS. 1A through 1C are schematic cross-sectional flowcharts showing a process for fabricating a conductive pattern according to an embodiment of the present invention.

In the present embodiment, the conductive pattern intended to be formed can serve as one of the components of a semiconductor device and have a predetermined height.

First, referring to FIG. 1A, a conductive layer 102 is formed on a substrate 100. The substrate 100 is, for example, a silicon substrate. A material of the conductive layer 102 is, for example, a metallic material, such as tungsten, aluminum, copper, and so forth. Besides, the conductive layer 102 is, for example, formed by performing a physical vapor deposition process.

Next, a patterned hard mask layer 104 is formed on the conductive layer 102. Here, the patterned hard mask layer 104 exposes a portion of the conductive layer 102. A material of the patterned hard mask layer 104 is, for example, carbon or a photoresist material. Besides, the patterned hard mask layer 104 is, for example, formed by first forming a hard mask material layer (not shown) on the conductive layer 102 and then patterning the hard mask material layer. When the material of the patterned hard mask layer 104 is carbon, the hard mask material layer is formed by performing a chemical vapor deposition process, for example. By contrast, when the material of the patterned hard mask layer 104 is the photoresist material, the hard mask material layer is formed by performing a spin coating process, for example.

After that, referring to FIG. 1B, the portion of the conductive layer 102 is removed by using the patterned hard mask layer 104 as a mask, and thereby a portion of the substrate 100 is exposed. The other portion of the conductive layer 102 becomes a patterned conductive layer 102′, and a gap 106 is formed in the patterned conductive layer 102′ and in the patterned hard mask layer 104. The height of the patterned conductive layer 102′ is less than a predetermined height of the conductive pattern, such that an aspect ratio of the patterned conductive layer 102′ is relatively small. The portion of the conductive layer 102 is removed by performing a dry etching process, for example.

Next, a dielectric layer 108 covering the patterned hard mask layer 104 and completely filling the gap 106 is formed on the substrate 100. The dielectric layer 108 is made of a dielectric material, such as silicon oxide. Besides, the dielectric layer 108 is, for example, formed by performing a chemical vapor deposition process.

Thereafter, referring to FIG. 1C, a portion of the dielectric layer 108 is removed to expose the patterned hard mask layer 104. The portion of the dielectric layer 108 is removed by performing an etching back process or a chemical-mechanical polishing process, for example.

After that, as shown in FIG. 1D, the patterned hard mask layer 104 is removed, so as to form openings 110 in the dielectric layer 108. Here, the openings 110 expose the patterned conductive layer 102′. The patterned hard mask layer 104 is removed by performing a dry etching process or a wet etching process, for example.

As indicated in FIG. 1E, a conductive layer 112 is then formed in the openings 110 and electrically connected to the patterned conductive layer 102′. The height of the conductive layer 112 is less than the predetermined height of the conductive patterns, such that the aspect ratio of the conductive layer 112 is relatively small. A material of the conductive layer 112 is, for example, a metallic material, such as tungsten, aluminum, copper, and so forth. Besides, the conductive layer 112 is formed by first forming a conductive material layer (not shown) filling the openings 110 on the dielectric layer 108 through performing a physical vapor deposition process and then removing the conductive material layer outside the openings 110 through performing a chemical-mechanical polishing process, which can also be referred to as a damascene process. So far, conductive patterns 114 are formed by the conductive layer 112 and the patterned conductive layer 102′.

As elaborated in the above embodiment, the conductive patterns 114 are step by step formed by the patterned conductive layer 102′ and the conductive layer 112. In addition, the aspect ratio of the patterned conductive layer 102′ and the aspect ratio of the conductive layer 112 are relatively small. As such, the distortion or collapse of the conductive patterns 114 can be prevented, and the conductive patterns 114 with outstanding quality can be manufactured.

Moreover, the small aspect ratio of the gap 106 enables the gap 106 to be completely filled with the dielectric layer 108 without forming the voids in the dielectric layer 108. Hence, the performance of the semiconductor device can be further improved.

In summary, the above embodiment has at least the following advantages:

1. In the method for fabricating the conductive pattern according to the present invention, the conductive pattern with outstanding quality can be manufactured when the distortion or collapse of the conductive pattern is prevented.

2. By conducting the method for fabricating the conductive pattern according to the present invention, the formation of the voids in the dielectric layer between the conductive patterns can be avoided, so as to improve the performance of the semiconductor device.

Although the present invention has been disclosed above by the embodiments, they are not intended to limit the present invention. Anybody skilled in the art can make some modifications and alterations without departing from the spirit and scope of the present invention. Therefore, the protecting range of the present invention falls in the appended claims.

What is claimed is:

1. A method for fabricating a conductive pattern, comprising:
forming a first conductive layer on a substrate;
forming a patterned hard mask layer on the first conductive layer; removing a portion of the first conductive layer by using the patterned hard mask layer as a mask, so as to expose a portion of the substrate;
forming a dielectric layer on the substrate, wherein the dielectric layer covers the patterned hard mask layer;
removing a portion of the dielectric layer to expose the patterned hard mask layer;
removing the patterned hard mask layer to form an opening in the dielectric layer; and
forming a second conductive layer in the opening.

2. The method for fabricating the conductive pattern as claimed in claim 1, wherein the conductive pattern comprises a conductive wire.

3. The method for fabricating the conductive pattern as claimed in claim 1, wherein a material of the first conductive layer comprises metal.

4. The method for fabricating the conductive pattern as claimed in claim 1, wherein a method for forming the first conductive layer comprises performing a physical vapor deposition process.

5. The method for fabricating the conductive pattern as claimed in claim 1, wherein a material of the patterned hard mask layer comprises carbon.

6. The method for fabricating the conductive pattern as claimed in claim 1, wherein a material of the patterned hard mask layer comprises a photoresist material.

7. The method for fabricating the conductive pattern as claimed in claim 1, wherein the step of forming the patterned hard mask layer comprises:
forming a hard mask material layer on the first conductive layer; and
patterning the hard mask material layer.

8. The method for fabricating the conductive pattern as claimed in claim 1, wherein a method for removing the portion of the first conductive layer comprises performing a dry etching process.

9. The method for fabricating the conductive pattern as claimed in claim 1, wherein a material of the dielectric layer comprises silicon oxide.

10. The method for fabricating the conductive pattern as claimed in claim 1, wherein a method for forming the dielectric layer comprises performing a chemical vapor deposition process.

11. The method for fabricating the conductive pattern as claimed in claim 1, wherein a method for removing the portion of the dielectric layer comprises performing an etching back process.

12. The method for fabricating the conductive pattern as claimed in claim 1, wherein a method for removing the portion of the dielectric layer comprises performing a chemical-mechanical polishing process.

13. The method for fabricating the conductive pattern as claimed in claim 1, wherein a method for removing the patterned hard mask layer comprises performing a dry etching process.

14. The method for fabricating the conductive pattern as claimed in claim 1, wherein a method for removing the patterned hard mask layer comprises performing a wet etching process.

15. The method for fabricating the conductive pattern as claimed in claim 1, wherein a material of the second conductive layer comprises metal.

16. The method for fabricating the conductive pattern as claimed in claim 1, wherein the step of forming the second conductive layer comprises:
forming a conductive material layer on the dielectric layer, wherein the opening is filled with the conductive material layer; and
removing the conductive material layer outside the opening.

17. The method for fabricating the conductive pattern as claimed in claim 16, wherein a method for forming the conductive material layer comprises performing a physical vapor deposition process.

18. The method for fabricating the conductive pattern as claimed in claim 16, wherein a method for removing the conductive material layer outside the opening comprises performing a chemical-mechanical polishing process.
